(19) United States
(12) Patent Application Publication
(10) Pub. No.: US 2023/0125153 A1
(43) Pub. Date: Apr. 27, 2023

(54) BONDING SHEET

(71) Applicant: NITTO DENKO CORPORATION, Ibaraki-shi, Osaka (JP)

(72) Inventors: Akiko TANAKA, Ibaraki-shi, Osaka (JP); Yuichiro SHISHIDO, Ibaraki-shi, Osaka (JP); Ayumi NISHIMARU, Ibaraki-shi, Osaka (JP)

(21) Appl. No.: 17/910,492

(22) PCT Filed: Mar. 5, 2021
(86) PCT No.: PCT/JP2021/008686

§ 371 Date: Sep. 9, 2022

(30) Foreign Application Priority Data
Mar. 12, 2020 (JP) 2020-043367

(51) Int. Cl. B23K 35/02; H05K 3/34; B23K 35/26; C09J 7/38; C09J 9/02

(52) U.S. Cl. CPC B23K 35/0238; H05K 3/3457; B23K 35/0244; B23K 35/264; B23K 35/262; C09J 7/38; C09J 9/02; C09J 2203/326; C09J 2479/088; C09J 2301/408

(57) ABSTRACT

A bonding sheet (X) of the present invention includes a matrix resin, a plurality of solder particles, and a plurality of flux particles, and has a sheet thickness T. In the bonding sheet (X), a particle size D₅₀ of the solder particles is 12 μm or less, a particle size D₅₀ of the flux particles is 30 μm or less, and a ratio of a particle size D₉₀ of the solder particles and a particle size D₉₀ of the flux particles to the sheet thickness T is 0.95 or less.

### TECHNICAL FIELD

The present invention relates to a bonding sheet for solder bonding.

### BACKGROUND ART

In mounting of an electronic component with respect to a wiring board, a terminal of the wiring board and a terminal of the electronic component may be solder-bonded using a solder paste containing solder particles. For example, the solder paste is supplied onto the terminal of the wiring board by a printing method such as screen printing, the electronic component is placed on the wiring board so that the electronic component terminal faces the substrate terminal via the solder paste, and then, the solder particles in the solder paste are once heated and melted to be aggregated, thereby forming a solder portion bonding both terminals. As the solder paste, a composition containing a thermosetting resin in addition to the solder particles may be used. The thermosetting resin is blended into the solder paste in order to form a cured resin portion around the solder portion in parallel with the formation of the solder portion by aggregation of the solder particles during a solder bonding process. Techniques regarding the solder bonding using the solder paste are described in, for example, Patent Document 1 below.

### CITATION LIST

### Patent Document

Patent Document 1: Japanese Unexamined Patent Publication No. 2006-150413

### SUMMARY OF THE INVENTION

### Problem to be Solved by the Invention

Recently, with high density of the wiring of the electronic component, in the electronic component and the wiring board mounted therewith, miniaturization of the terminal is advanced, and narrow terminals tend to be disposed at a fine pitch. However, according to the above-described method in which the solder paste is supplied onto the terminals by a printing method, existing printing facilities may not be able to appropriately supply the solder paste onto each of the plurality of terminals which are disposed at a fine pitch. As a result, it may not be possible to appropriately form the solder portion between objects to be bonded. That is, when the solder paste is used as a solder bonding material, it may not be possible to form the plurality of solder portions between the objects to be bonded at a fine pitch.

The present invention provides a bonding sheet suitable for forming a plurality of solder portions which bond objects to be bonded at a fine pitch.

### Means for Solving the Problem

The present invention [1] includes a bonding sheet including a matrix resin, a plurality of solder particles, and a plurality of flux particles, and having a sheet thickness T, wherein a particle size D₅₀ of the solder particles is 12 μm or less, a particle size D₅₀ of the flux particles is 30 μm or less, and a ratio of a particle size D₉₀ of the solder particles and a particle size D₉₀ of the flux particles to the sheet thickness T is 0.95 or less.

In the present bonding sheet, the particle size D₅₀ of the contained solder particles which are solder portion forming materials is 12 μm or less, the particle size D₅₀ of the contained flux particles for developing an oxide film removal function with respect to the solder particles is 30 μm or less, and the ratio of the particle size D₉₀ of both particles with respect to the sheet thickness T is 0.95 or less. Such a configuration is suitable for thinly fabricating the present bonding sheet with its surface unevenness suppressed, even when the sheet thickness T is, for example, 50 μm or less.

Then, the above-described configuration in which the particle size D₅₀ of the solder particles is 12 μm or less in the present bonding sheet suitable for being thinly fabricated is suitable for forming a minute solder portion corresponding to its thinness from the solder particles (plurality of solder particles present in a predetermined subregion) between objects to be bonded such as between predetermined terminals using the present bonding sheet. Being suitable for forming a minute solder portion is preferable for forming the plurality of solder portions at a fine pitch.

Further, the above-described configuration in which the particle size D₅₀ of the contained flux particles of the present bonding sheet is 30 μm or less is suitable for realizing a uniform dispersion state of the flux particles with respect to the solder particles having the particle size D₅₀ of 12 μm or less in the matrix resin, and therefore, is suitable for developing the excellent oxide film removal function with respect to the solder particles in the flux particles during a solder bonding process. By developing the oxide film removal function of the flux particles with respect to the solder particles during heating for solder bonding, the solder particles are appropriately melted and aggregated.

According to the present bonding sheet in which each provided configuration can cooperate as described above, for example, when the electronic component in which narrow terminals are disposed on the surface at a fine pitch is used for the solder bonding for being mounted on the wiring board (solder bonding between a plurality of electronic component terminals and a plurality of substrate terminals facing thereto), a plurality of solder portions are easily formed at a fine pitch using a self-aggregating effect (self-alignment effect) of the melted solder particles for each facing terminal. That is, the present bonding sheet is suitable for forming the plurality of solder portions bonding the objects to be bonded at a fine pitch.

The present invention [2] includes the bonding sheet described in the above-described [1], wherein a ratio of the particle size D₅₀ of the flux particles to the particle size D₅₀ of the solder particles is 8 or less.

Such a configuration is suitable for realizing the uniform dispersion state of the flux particles with respect to the solder particles having the particle size D₅₀ of 12 μm or less in the matrix resin, and therefore, is suitable for developing the excellent oxide film removal function with respect to the solder particles in the flux particles during the solder bonding process.

The present invention [3] includes the bonding sheet described in the above-described [1] or [2], wherein the sheet thickness T is 50 μm or less.

The smaller the sheet thickness T, the easier to cope with the fine pitch of a bump forming portion.

The present invention [4] includes the bonding sheet described in any one of the above-described [1] to [3], wherein a ratio of a second tensile elastic modulus at 25° C. of the bonding sheet after heat treatment at 160° C. for 20 seconds to a first tensile elastic modulus at 25° C. is 5 or more.

Such a configuration is suitable for achieving both its temporary fixability in a state of attaching the present bonding sheet to one object region to be bonded (i.e., a state of temporarily fixed) in the solder bonding process using the present bonding sheet, and bonding strength between facing object regions to be bonded which are bonded by the present bonding sheet through the solder bonding process.

The present invention [5] includes the bonding sheet described in any one of the above-described [1] to [4], wherein the first tensile elastic modulus at 25° C. of the bonding sheet is 10 MPa or less.

Such a configuration is suitable for ensuring its temporary fixability in a state of attaching the present bonding sheet to one object region to be bonded during the solder bonding process using the present bonding sheet.

The present invention [6] includes the bonding sheet described in any one of the above-described [1] to [5], wherein the second tensile elastic modulus at 25° C. of the bonding sheet after heat treatment at 160° C. for 20 seconds is above 10 MPa.

Such a configuration is suitable for ensuring the bonding strength between the facing object regions to be bonded which are bonded by the present bonding sheet through the solder bonding process using the present bonding sheet.

The present invention [7] includes the bonding sheet described in any one of the above-described [1] to [6], wherein a ratio of a second shear pressure-sensitive adhesive force at 25° C. of the bonding sheet showing for a polyimide plane surface after the bonding sheet being bonded to the polyimide plane surface and subsequently, subjected to a heat treatment at 160° C. for 20 seconds to a first shear pressure-sensitive adhesive force at 25° C. of the bonding sheet showing for the polyimide plane surface after the bonding sheet being bonded to the polyimide plane surface is 1.2 or more.

Such a configuration is suitable for achieving both its temporary fixability in a state of attaching the present bonding sheet to one object region to be bonded during the solder bonding process using the present bonding sheet, and the bonding strength between the facing object regions to be bonded which are bonded by the present bonding sheet through the solder bonding process.

The present invention [8] includes the bonding sheet described in any one of the above-described [1] to [7] further including a colorant.

Such a configuration is preferable to develop light shielding properties and anti-reflective properties in the bonding sheet.

The present invention [9] includes the bonding sheet described in the above-described [8], wherein a total light transmittance at least after heating is 70% or less.

Such a configuration is preferable to ensure the sufficient light shielding properties and anti-reflective properties in the bonding sheet.

### BRIEF DESCRIPTION OF THE DRAWINGS

FIG. 1 shows a cross-sectional schematic view in one embodiment of a bonding sheet of the present invention.

FIG. 2 shows one example of a solder bonding method using the bonding sheet shown in FIG. 1.

### DESCRIPTION OF EMBODIMENTS

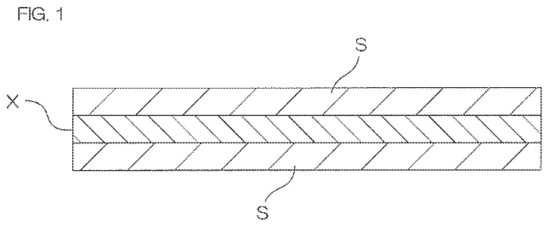

FIG. 1 shows a cross-sectional schematic view of a bonding sheet X of one embodiment of the present invention. The bonding sheet X is a sheet for solder bonding, contains a matrix resin, a plurality of solder particles, and a plurality of flux particles, and has a sheet thickness T. The bonding sheet X may have a first separator S covering one surface in a thickness direction thereof, and a second separator S covering the other surface (illustratively illustrating a case where the bonding sheet X has both the first separator S and the second separator S). Also, the bonding sheet X may have a long sheet shape. When the bonding sheet X has a long sheet shape, it may have a roll form which is wound up. Or, the bonding sheet X may also have a single-sheet form.

Examples of the solder particles include solder materials containing no lead (lead-free solder) from the viewpoint of environmental suitability. Examples of the solder material include tin-bismuth-based alloys and tin-silver-based alloys. Examples of the tin-bismuth-based alloy include tin-bismuth alloys (Sn—Bi) and tin-bismuth-indium alloys (Sn—Bi—In). Examples of the tin-silver-based alloy include tin-silver alloys (Sn—Ag) and tin-silver-copper alloys (Sn—Ag—Cu). From the viewpoint of low temperature bonding, as the material for the solder particles, preferably, a tin-bismuth alloy and a tin-bismuth-indium alloy are used. One kind of solder particles may be used alone, or two or more kinds of solder particles may be used in combination.

A content ratio of the tin in the tin-bismuth-based alloy is, for example, 10% by mass or more, preferably 20% by mass or more, more preferably 25% by mass or more, and for example, 75% by mass or less, preferably 50% by mass or less, more preferably 30% by mass or less. A content ratio of the bismuth in the tin-bismuth-based alloy is, for example, 25% by mass or more, preferably 55% by mass or more, and for example, 90% by mass or less, preferably 75% by mass or less. When the tin-bismuth-based alloy contains the indium, a content ratio of the indium is, for example, 8% by mass or more, preferably 12% by mass or more, more preferably 18% by mass or more, and for example, 30% by mass or less, preferably 25% by mass or less.

The melting point of the solder material (melting point of the solder particles) is, for example, 240° C. or less, preferably 200° C. or less, more preferably 180° C. or less, and for example, 70° C. or more, preferably 100° C. or more, more preferably 120° C. or more. The melting point of the solder material can be determined by differential scanning calorimetry (DSC) (the same applies to the melting point of a material for flux particles to be described later).

Examples of a shape of the solder particle include spherical shapes, plate shapes, and needle shapes, and preferably, a spherical shape is used.

A particle size D₅₀ of the solder particles is 12 μm or less, preferably 8 μm or less, more preferably 4 μm or less. A particle size D₉₀ of the solder particles is preferably 30 μm or less, more preferably 20 μm or less, further more preferably 10 μm or less, as long as the it is larger than the particle size D₅₀. These configurations are suitable for suppressing precipitation of the solder particles in a composition for forming a bonding sheet during a production process of the bonding sheet X, and therefore, are suitable for realizing an excellent dispersion state of the solder particles in the bonding sheet X to be formed. Further, the configuration regarding smallness of the solder particles is suitable for thinly fabricating the bonding sheet X with its surface unevenness suppressed. In addition, the configuration is suitable for forming a minute solder portion corresponding to its thinness from the solder particles using the bonding sheet X. From the viewpoint of appropriately forming the solder portion between objects to be solder-bonded, the particle size D₅₀ of the solder particles is, for example, 10 nm or more, and the particle size D₉₀ of the solder particles is, for example, 20 nm or more. The particle size D₅₀ and the particle size D₉₀ of the solder particles are determined by measurement using a laser diffraction particle size analyzer (the same applies to a particle size D₅₀ and a particle size D₉₀ of the flux particles to be described later).

A ratio of the particle size D₉₀ of the solder particles to the sheet thickness T is 0.95 or less, preferably 0.8 or less, more preferably 0.6 or less, further more preferably 0.4 or less. Such a configuration is suitable for thinly fabricating the bonding sheet X with its surface unevenness suppressed. The ratio of the particle size D₉₀ of the solder particles to the sheet thickness T is, for example, 0.001 or more.

The solder particle content in the bonding sheet X is, for example, 50 parts by mass or more, preferably 100 parts by mass or more, more preferably 120 parts by mass or more with respect to 100 parts by mass of the matrix resin. Also, a volume ratio of the solder particles in the bonding sheet X is, for example, 5% by volume or more, preferably 10% by volume or more, more preferably 15% by volume or more. These configurations are suitable for ensuring cohesiveness of the solder particles in the bonding sheet X during the solder bonding process. Also, the solder particle content in the bonding sheet X is, for example, 600 parts by mass or less, preferably 450 parts by mass or less, more preferably 170 parts by mass or less with respect to 100 parts by mass of the matrix resin. Also, the volume ratio of the solder particles in the bonding sheet X is, for example, 80% by volume or less, preferably 50% by volume or less, more preferably 30% by volume or less. These configurations are preferable from the viewpoint of easy fabrication (sheet moldability) of the bonding sheet X as a sheet member.

The flux particles are a component which develops an oxide film removal function with respect to the solder particles in the bonding sheet X at the time of heating for the solder bonding, and the solder particles can be appropriately melted to be aggregated by the oxide film removal.

Examples of a material for the flux particles include organic acid salts such as organic acids, quinolinol derivatives, and metal carbonyl acid salts. Examples of the organic acid include aliphatic carboxylic acid and aromatic carboxylic acid. Examples of the aliphatic carboxylic acid include aliphatic dicarboxylic acid, and specific examples of the aliphatic dicarboxylic acid include adipic acid, malic acid, malonic acid, succinic acid, glutaric acid, pimelic acid, suberic acid, and sebacic acid. Examples of the aromatic carboxylic acid include benzoic acid, 2-phenoxybenzoic acid, phthalic acid, diphenylacetic acid, trimellitic acid, and pyromellitic acid. As the flux particles, preferably, at least one kind of particles selected from the group consisting of malic acid and adipic acid is used. These flux particles may be used alone or in combination of two or more.

The melting point of the flux particles is, for example, 200° C. or less, preferably 180° C. or less, more preferably 160° C. or less, and for example, 100° C. or more, preferably 120° C. or more, more preferably 130° C. or more.

A shape of the flux particle is not particularly limited, and examples of the shape thereof include plate shapes, needle shapes, and spherical shapes.

The particle size D₅₀ of the flux particles is 30 μm or less, preferably 20 μm or less, more preferably 10 μm or less. The particle size D₉₀ of the flux particles is preferably 60 μm or less, more preferably 40 μm or less, further more preferably 20 μm or less, as long as it is larger than the particle size D₅₀. These configurations are suitable for suppressing the precipitation of the flux particles in the composition for forming a bonding sheet during the production process of the bonding sheet X, and therefore, are suitable for realizing the excellent dispersion state of the flux particles in the bonding sheet X to be formed. Further, the configuration regarding the smallness of the flux particles is suitable for thinly fabricating the bonding sheet X with its surface unevenness suppressed. In the matrix resin, from the viewpoint of realizing a uniform dispersion state of the flux particles with respect to the solder particles having the particle size D₅₀ of 12 μm or less, the particle size D₅₀ of the flux particles is, for example, 20 nm or more.

A ratio of the particle size D₅₀ of the flux particles to the particle size D₅₀ of the solder particles is preferably 8 or less, more preferably 6 or less, further more preferably 3 or less, particularly preferably 1.8 or less, and for example, 0.1 or more. The ratio of the particle size D₉₀ of the flux particles to the particle size D₉₀ of the solder particles is preferably 8 or less, more preferably 5 or less, further more preferable 2.5 or less, and for example, 0.1 or more. These configurations are preferable from the viewpoint of realizing the uniform dispersion state of the flux particles with respect to the solder particles having the particle size D₅₀ of 12 μm or less in the matrix resin.

A ratio of the particle size D₉₀ of the flux particles to the sheet thickness T is 0.95 or less, preferably 0.9 or less, more preferably 0.8 or less. Such a configuration is suitable for thinly fabricating the bonding sheet X with its surface unevenness suppressed. The ratio of the particle size D₉₀ of the flux particles to the sheet thickness T is, for example, 0.001 or more.

The flux particle content in the bonding sheet X is, for example, 10 parts by mass or more, preferably 30 parts by mass or more, more preferably 40 parts by mass or more with respect to 100 parts by mass of the matrix resin. Also, a volume ratio of the flux particles in the bonding sheet X is, for example, 10% by volume or more, preferably 20% by volume or more, more preferably 30% by volume or more. These configurations are suitable for ensuring the cohesiveness of the solder particles in the bonding sheet X during the solder bonding process. Also, the flux particle content in the bonding sheet X is, for example, 100 parts by mass or less, preferably 80 parts by mass or less, more preferably 60 parts by mass or less with respect to 100 parts by mass of the matrix resin. Also, the volume ratio of the flux particles in the bonding sheet X is, for example, 100% by volume or less, preferably 80% by volume or less, more preferably 50% by volume or less. These configurations are preferable from the viewpoint of easy fabrication (sheet moldability) of the bonding sheet X as a sheet member.

The matrix resin contains a thermosetting resin and a thermoplastic resin in the present embodiment.

Examples of the thermosetting resin include epoxy resins, oxetane resins, thermosetting (meth)acrylic resins, diallyl phthalate resins, thermosetting polyesters, and maleimide resins, and preferably, an epoxy resin which is liquid at normal temperature before curing is used. These thermosetting resins may be used alone or in combination of two or more.

Examples of the epoxy resin include aromatic epoxy resins such as bisphenol epoxy resins (for example, bisphenol A epoxy resin, bisphenol F epoxy resin, bisphenol S epoxy resin, hydrogenated bisphenol A epoxy resin, dimer acid modified bisphenol epoxy resin, etc.), novolac epoxy resins (for example, phenol novolac epoxy resin, cresol novolac epoxy resin, biphenyl epoxy resin, etc.), naphthalene epoxy resins, fluorene epoxy resins (for example, bisarylfluorene epoxy resin etc.), and triphenylmethane epoxy resins (for example, trishydroxyphenylmethane epoxy resin etc.); nitrogen-containing ring epoxy resins such as triepoxypropyl isocyanurate (triglycidyl isocyanurate) and hydantoin epoxy resins; aliphatic epoxy resins; alicyclic epoxy resins (for example, dicyclo ring epoxy resin etc.); glycidyl ether epoxy resins; and glycidylamine epoxy resins. As the epoxy resin, preferably, a bisphenol epoxy resin which is liquid at normal temperature before curing is used, more preferably, a bisphenol A epoxy resin which is liquid at normal temperature before curing is used.

An epoxy equivalent of the epoxy resin is, for example, 80 g/eq or more, preferably 100 g/eq or more, and for example, 500 g/eq or less, preferably 400 g/eq or less.

A temperature at which the thermosetting resin cures is, for example, 90° C. or more, preferably 140° C. or more, and for example, 250° C. or less, preferably 230° C. or less.

A content ratio of the thermosetting resin in the bonding sheet X is preferably 30% by volume or more, more preferably 40% by volume or more, and preferably 70% by volume or less, more preferably 60% by volume or less. Further, a content ratio of the thermosetting resin in the matrix resin is preferably 50% by volume or more, more preferably 60% by volume or more, and preferably 90% by volume or less, more preferably 80% by volume or less. These configurations are suitable for ensuring the bonding strength with respect to an object to be bonded of the bonding sheet X through the solder bonding process.

When the epoxy resin is used as the thermosetting resin, the matrix resin may further contain a phenol resin as a curing agent of the epoxy resin. Examples of the phenol resin include novolac phenol resins and resol phenol resins. Examples of the novolac phenol resin include phenol novolac resins, phenol aralkyl resins, cresol novolac resins, tert-butyl phenol novolac resins, and nonylphenol novolac resins. When the matrix resin contains the epoxy resin, and the phenol resin as a curing agent thereof, both resins are blended at a ratio of hydroxyl groups in the phenol resin of preferably 0.5 to 2.0 equivalents, more preferably 0.8 to 1.2 equivalents with respect to 1 equivalent of epoxy groups in the epoxy resin. Such a configuration is suitable for sufficiently advancing a curing reaction of the epoxy resin and the phenol resin in the bonding sheet X in the solder bonding process.

Examples of the thermoplastic resin include acrylic resins, rubber such as polybutadiene, styrene-butadiene-styrene copolymers, polyolefin (for example, polyethylene, polypropylene, ethylene-propylene copolymer, etc.), phenoxy resins, polyester resins, thermoplastic polyurethane, thermoplastic polyimide, thermoplastic polyamide, and polyacetal resins, and preferably, an acrylic resin which is solid at normal temperature is used. These thermoplastic resins may be used alone or in combination of two or more.

The acrylic resin is a polymer of a monomer component containing alkyl (meth)acrylate. “(Meth)acrylate” refers to an acrylic acid and/or a methacrylic acid.

An example of the alkyl (meth)acrylate includes an alkyl (meth)acrylate having a straight-chain or branched alkyl group having 1 to 20 carbon atoms. Examples of the alkyl (meth)acrylate include methyl (meth)acrylate, ethyl (meth)acrylate, propyl (meth)acrylate, n-butyl (meth)acrylate, isopropyl (meth)acrylate, isobutyl (meth)acrylate, s-butyl (meth)acrylate, t-butyl (meth)acrylate, pentyl (meth)acrylate, isopentyl (meth)acrylate, neopentyl (meth)acrylate, hexyl (meth)acrylate, heptyl (meth)acrylate, 2-ethylhexyl (meth)acrylate, octyl (meth)acrylate, isooctyl (meth)acrylate, nonyl (meth)acrylate, isononyl (meth)acrylate, decyl (meth)acrylate, isodecyl (meth)acrylate, undecyl (meth)acrylate, dodecyl (meth)acrylate, isotridecyl (meth)acrylate, tetradecyl (meth)acrylate, isotetradecyl (meth)acrylate, pentadecyl (meth)acrylate, hexadecyl (meth)acrylate, heptadecyl (meth)acrylate, octadecyl (meth)acrylate, isooctadecyl (meth)acrylate, nonadecyl (meth)acrylate, and eicosyl (meth)acrylate. These alkyl (meth)acrylates may be used alone or in combination of two or more.

A ratio of the alkyl (meth)acrylate in the monomer component is preferably 70% by mass or more, more preferably 80% by mass or more, further more preferably 90% by mass or more. Further, the ratio of the alkyl (meth)acrylate in the monomer component is preferably 99.5% by mass or less, more preferably 99% by mass or less.

The monomer component may contain one or two or more kinds of copolymerizable monomers copolymerizable with the alkyl (meth)acrylate. The copolymerizable monomer contains a functional group-containing vinyl monomer and an aromatic vinyl monomer. The copolymerizable monomer serves to modify the acrylic polymer such as ensuring cohesive force of the acrylic polymer. A ratio of the copolymerizable monomer in the monomer component is preferably 0.1% by mass or more, more preferably 0.5% by mass or more, further more preferably 1.5% by mass or more from the viewpoint of ensuring an effect by using the copolymerizable monomer. The ratio of the copolymerizable monomer in the monomer component is preferably 10% by mass or less, more preferably 5% by mass or less, further more preferably 3% by mass or less.

Examples of the functional group-containing vinyl monomer include carboxy group-containing vinyl monomers, acid anhydride vinyl monomers, hydroxyl group-containing vinyl monomers, sulfo group-containing vinyl monomers, phosphoric acid group-containing vinyl monomers, cyano group-containing vinyl monomers, and glycidyl group-containing vinyl monomers. These functional group-containing vinyl monomers may be used alone or in combination of two or more.

Examples of the carboxy group-containing vinyl monomer include acrylic acid, methacrylic acid, 2-carboxyethyl (meth)acrylate, carboxypentyl (meth)acrylate, itaconic acid, maleic acid, fumaric acid, and crotonic acid.

Examples of the acid anhydride vinyl monomer include maleic anhydride and itaconic anhydride.

Examples of the hydroxyl group-containing vinyl monomer include 2-hydroxyethyl (meth)acrylate, 2-hydroxypropyl (meth)acrylate, 2-hydroxybutyl (meth)acrylate, 3-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethylcyclohexyl)methyl (meth)acrylate.

Examples of the sulfo group-containing vinyl monomer include styrene sulfonic acid, allyl sulfonic acid, sodium vinylsulfonate, 2-(meth)acrylamide-2-methylpropanesulfonic acid, (meth)acrylamidopropane sulfonic acid, sulfopropyl (meth)acrylate, and (meth)acryloyloxynaphthalene sulfonic acid.

An example of the phosphoric acid group-containing vinyl monomer includes 2-hydroxyethylacryloyl phosphate.

Examples of the cyano group-containing vinyl monomer include acrylonitrile and methacrylonitrile.

Examples of the glycidyl group-containing vinyl monomer include glycidyl (meth)acrylate and (meth)acrylic acid-2-ethylglycidyl ether.

Examples of the aromatic vinyl monomer include styrene, chloro styrene, chloromethylstyrene, and α-methylstyrene.

A mixing ratio of the copolymerizable monomer in the monomer component is, for example, 50% by mass or less, preferably 25% by mass or less, and for example, 1% by mass or more.

The acrylic resin is preferably a polymer of a monomer component containing an alkyl (meth)acrylate, a hydroxyl group-containing vinyl monomer, and an aromatic vinyl monomer, and more preferably a polymer of a monomer component containing an alkyl (meth)acrylate, a hydroxyl group-containing vinyl monomer, and styrene.

A weight average molecular weight Mw of the acrylic resin is, for example, 8000 or more, preferably 10000 or more, and for example, 2 million or less, preferably 1.5 million or less. The weight average molecular weight (value in terms of standard polystyrene) of the acrylic resin is calculated by GPC.

A glass transition temperature Tg of the acrylic resin is, for example, −100° C. or more, preferably −50° C. or more, and for example, 100° C. or less, preferably 50° C. or less.

As for the glass transition temperature (Tg) of the polymer, a glass transition temperature (theoretical value) determined based on the following formula of Fox can be used. The formula of Fox is a relational expression between the glass transition temperature Tg of the polymer and a glass transition temperature Tgi of a homopolymer of a monomer constituting the polymer. In the following formula of Fox, Tg represents the glass transition temperature (° C.) of the polymer, Wi represents a weight fraction of a monomer i constituting the polymer, and Tgi represents the glass transition temperature (° C.) of the homopolymer formed from the monomer i. Literature values can be used for the glass transition temperature of the homopolymer, and for example, in “Polymer Handbook” (4th edition, John Wiley & Sons, Inc., 1999) and “New Polymer Library 7 Introduction to Synthetic Resin for Paints” (written by Kyozo Kitaoka, Polymer Publication Society, 1995), the glass transition temperatures of various homopolymers are listed. On the other hand, the glass transition temperature of the homopolymer of the monomer can be also determined by the method specifically described in Japanese Unexamined Patent Publication No. 2007-51271.

Formula of Fox 1/(273+Tg)=Σ[Wi/(273+Tgi)]

A content ratio of the thermoplastic resin in the bonding sheet X is preferably 2% by volume or more, more preferably 15% by volume or more, and preferably 50% by volume or less, more preferably 30% by volume or less, further more preferably 20% by volume or less. Further, a content ratio of the thermoplastic resin in the matrix resin is preferably 5% by mass or more, more preferably 15% by mass or more, and preferably 60% by mass or less, more preferably 50% by mass or less. These configurations are suitable for ensuring the moldability of the bonding sheet X.

The matrix resin may contain a thermosetting catalyst. The thermosetting catalyst is a catalyst which promotes curing of the thermosetting resin by heating, and examples thereof include imidazole-based compounds, triphenylphosphine-based compounds, amine-based compounds, and trihalogen borane-based compounds. Examples of the imidazole-based compound include 2-methylimidazole, 2-undecylimidazole, 2-heptadecylimidazole, 1,2-dimethyimidazole, 2-ethyl-4-methylimidazole, 2-phenylimidazole, 2-phenyl-4-methylimidazole, 1-benzyl-2-methylimidazole, 1-benzyl-2-phenylimidazole, 1-cyanoethyl-2-methylimidazole, and 1-cyanoethyl-2-undecylimidazole. Examples of the triphenylphosphine-based compound include triphenylphosphine, tributylphosphine, diphenyltolylphosphine, tetraphenylphosphonium bromide, methyltriphenylphosphonium bromide, methyltriphenylphosphonium chloride, methoxymethyltriphenylphosphonium, and benzyltriphenylphosphonium chloride. Examples of the amine-based compound include monoethanolamine trifluoroborate and dicyandiamide. An example of the trihalogen borane-based compound includes trichloroborane. These may be used alone or in combination of two or more. As the thermosetting catalyst, preferably, an imidazole-based compound is used, more preferably, 1-benzyl-2-phenylimidazole is used.

When the thermosetting catalyst is used, the thermosetting catalyst content in the matrix resin is preferably 0.1 parts by mass or more, more preferably 1 part by mass or more, and preferably 7 parts by mass or less, more preferably 5 parts by mass or less with respect to 100 parts by mass of the thermosetting resin.

A content ratio of the matrix resin in the bonding sheet X is preferably 40% by volume or more, more preferably 55% by volume or more, and preferably 80% by volume or less, more preferably 70% by volume or less. Such a configuration is suitable for balancing easy aggregation of a melted solder and easy formation of solder portions isolated from each other during the heating process in the solder bonding.

The bonding sheet X may also contain another component if necessary. Examples of the other component include colorants and coupling agents.

It is preferable that the bonding sheet X contains the colorant in order to develop light shielding properties and anti-reflective properties in the bonding sheet X. When at least one object to be bonded by the bonding sheet X has transparency, the light shielding properties may be required to prevent or inhibit light passing through the transparent object to be bonded from reaching the other object to be bonded. When at least one object to be bonded by the bonding sheet X has transparency, the anti-reflexive properties may be required to prevent or inhibit reflection of the light passing through the transparent object to be bonded to reach the other object to be bonded.

Examples of the colorant include black colorants, cyan colorants, magenta colorants, or yellow colorants as pigments or dyes. From the viewpoint of ensuring engraving by laser marking or the like, a black colorant is preferable. Examples of the black colorant include carbon black, graphite (black lead), copper oxide, manganese dioxide, azo-based pigments such as azomethine azo black, aniline black, perylene black, titanium black, and cyanine black. Further, as the colorant, a compound which is colored by radiation irradiation such as ultraviolet rays or heating may be also used. Examples of the compound include leuco dyes, triarylmethane dyes, diphenylmethane dyes, fluoran dyes, spiropyran dyes, and rhodamine dyes. These may be used alone or in combination of two or more.

When the bonding sheet X contains the colorant, a content ratio of the colorant in the bonding sheet X is, for example, 0.01% by mass or more, and for example, 1% by mass or less. From the viewpoint of developing the excellent light shielding properties and anti-reflective properties in the bonding sheet X, the colorant content in the bonding sheet X is preferably 0.1 parts by mass or more, more preferably 1 part by mass or more, further more preferably 2 parts by mass or more with respect to 100 parts by mass of the matrix resin.

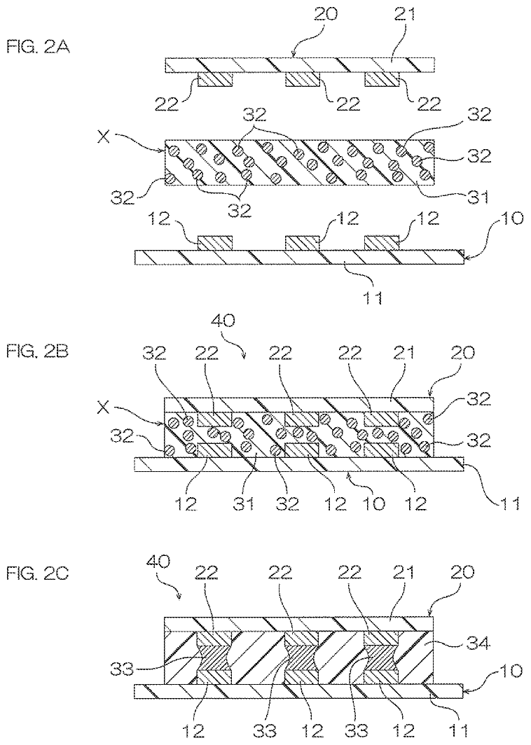

When the bonding sheet X contains the colorant, a total light transmittance of the bonding sheet X at least after heating is preferably 70% or less, more preferably 60% or less, further more preferably 50% or less, particularly preferably 40% or less. The bonding sheet X may have the total light transmittance, for example, by the heating in the heating step to be described later (FIG. 2C), or may have the total light transmittance prior to the heating, for example, at the end of the production process (that is, may be produced as the bonding sheet X having such a total light transmittance). Such a configuration regarding the total light transmittance of the bonding sheet X is preferable to ensure the sufficient light shielding properties and anti-reflective properties in the bonding sheet. The total light transmittance of the bonding sheet X can be measured by a method to be described later regarding Examples.

The bonding sheet X can be, for example, produced as follows.

First, a thermosetting resin, a thermoplastic resin, solder particles, flux particles, and another component (thermosetting catalyst etc.) which is blended if necessary are mixed in a solvent, thereby preparing a composition. The composition is preferably adjusted to the predetermined concentration. Examples of the solvent include methyl ethyl ketone, acetylacetone, and toluene.

Next, the obtained composition is coated on a separator to form a coating film, and then, the coating film is dried. A drying temperature is a softening temperature of the thermoplastic resin or more, below the melting point of the solder particles and the flux particles, and below a curing temperature of the thermosetting resin, and is, for example, 60° C. or more, preferably 75° C. or more, and for example, 130° C. or less, preferably 120° C. or less.

The bonding sheet X can be, for example, produced as described above.

A thickness of the bonding sheet X, that is, the sheet thickness T is preferably 50 μm or less, more preferably 30 μm or less, further more preferably 20 μm or less. Also, the sheet thickness T is, for example, 5 μm or more, as long as the ratio of each particle size D₉₀ of the solder particles and the flux particles to the sheet thickness T is 0.95 or less. The smaller the sheet thickness T, the easier to cope with a fine pitch of a bump forming portion.

A tensile elastic modulus (first tensile elastic modulus) at 25° C. of the bonding sheet X is preferably 10 MPa or less, more preferably 8 MPa or less, and preferably 1 MPa or more, more preferably 2 MPa or more. Such a configuration is suitable for ensuring its temporary fixability in a state of attaching the bonding sheet X to one object region to be bonded (i.e., a state of temporarily fixed) in the solder bonding process using the bonding sheet X. The tensile elastic modulus is measured by a tensile elastic modulus measurement method to be described later regarding the bonding sheet of Examples to be described below.

A tensile elastic modulus (second tensile elastic modulus) at 25° C. of the bonding sheet X after heat treatment at 160° C. for 20 seconds is preferably above 10 MPa, more preferably 20 MPa or more, and preferably 300 MPa or less, more preferably 200 MPa or less. Such a configuration is suitable for ensuring the bonding strength between facing object regions to be bonded which are bonded by the bonding sheet X through the solder bonding process using the bonding sheet X.

A ratio of the above-described second tensile elastic modulus to the above-described first tensile elastic modulus is preferably 5 or more, more preferably 8 or more. Such a configuration is suitable for achieving both its temporary fixability in a state of attaching the bonding sheet X to one object region to be bonded during the solder bonding process using the bonding sheet X, and the bonding strength between the facing object regions to be bonded which are bonded by the bonding sheet X through the solder bonding process.

A shear pressure-sensitive adhesive force (first shear pressure-sensitive adhesive force) at 25° C. of the bonding sheet X showing for a polyimide plane surface after the bonding sheet X being bonded to the polyimide plane surface is preferably 0.1 MPa or more, more preferably 0.2 MPa or more, and preferably 1 MPa or less, more preferably 0.8 MPa or less. Such a configuration is suitable for achieving both the temporary fixability in a state of attaching the bonding sheet X to one object region to be bonded during the solder bonding process using the bonding sheet X, and easy peeling from the region in a case of re-attachment if necessary. The shear pressure-sensitive adhesive force is measured by a shear pressure-sensitive adhesive force measurement method to be described later regarding the bonding sheet of Examples to be described later.

A shear pressure-sensitive adhesive force (second shear pressure-sensitive adhesive force) at 25° C. of the bonding sheet X showing for the polyimide plane surface after the bonding sheet X being bonded to the polyimide plane surface and subsequently, subjected to a heat treatment at 160° C. for 20 seconds is preferably 0.3 MPa or more, more preferably 0.6 MPa or more, and preferably 3 MPa or less, more preferably 2 MPa or less. Such a configuration is suitable for ensuring the bonding strength between the facing object regions to be bonded which are bonded by the bonding sheet X through the solder bonding process using the bonding sheet X.

A ratio of the above-described second shear pressure-sensitive adhesive force to the above-described first shear pressure-sensitive adhesive force is preferably 1.2 or more, more preferably 1.8 or more, and preferably 5 or less, more preferably 3.5 or less. Such a configuration is suitable for achieving both its temporary fixability in a state of attaching the bonding sheet X to one object region to be bonded during the solder bonding process using the bonding sheet X, and the bonding strength between the facing object regions to be bonded which are bonded by the bonding sheet X through the solder bonding process.

FIG. 2 shows one example of a solder bonding method using the bonding sheet X.

In the present method, first, as shown in FIG. 2A, a wiring board 10, an electronic component 20, and the bonding sheet X are prepared. The wiring board 10 is one example of one object to be bonded, and has a substrate 11 and a plurality of terminals 12. The substrate 11 is, for example, an insulating substrate having a flat plate shape. The terminals 12 consist of metals. The plurality of terminals 12 are isolated from each other. The maximum length of the terminal 12 is, for example, 10 μm or more, and for example, 200 μm or less. An interval between the terminals 12 is, for example, 10 μm or more, and for example, 200 μm or less. The electronic component 20 is one example of the other object to be bonded, and has a body portion 21 whose surface is resin-sealed and a plurality of terminals 22 which are electrically connected to the inside of the component. The terminal 22 is made of metal. The plurality of terminals 22 are isolated from each other. The plurality of terminals 22 are provided in an arrangement and size that can face the plurality of terminals 12 of the wiring board 10. For the bonding sheet X, a matrix resin 31 and solder particles 32 are illustrated.

Next, as shown in FIG. 2B, the wiring board 10, the bonding sheet X, and the electronic component 20 are laminated. Specifically, the wiring board 10 and the electronic component 20 are compressively bonded via the bonding sheet X so that the respective terminals 12 and 22 face each other, and the terminals 12 and 22 are buried in the bonding sheet X. Thus, a laminate 40 is obtained.

Next, by heating the laminate 40, as shown in FIG. 2C, a solder portion 33 is formed between each of the terminals 12 and 22 (heating step). A heating temperature is the melting point of the solder particles 32 and the flux particles or more, the softening point of the thermoplastic resin or more, and the curing temperature of the thermosetting resin or more. The heating temperature is appropriately determined in accordance with the kind of the thermosetting resin, the thermoplastic resin, the solder particles, and the flux particles, and is, for example, 120° C. or more, preferably 130° C. or more, and for example, 170° C. or less, preferably 160° C. or less. Further, the heating time is, for example, 3 seconds or more, and for example, 30 seconds or less, preferably 20 seconds or less.

By the short-time heating in the heating step, in the bonding sheet X, the thermoplastic resin is melted, the flux particles are melted, and the oxide film removal function of the surfaces of the solder particles is developed. Then, the solder particles are melted and aggregated, and gather between the terminals 12 and 22 (self-alignment), so that curing of the thermosetting resin progresses around the solder where the particles gather. By lowering the temperature after the completion of the heating process, the solder material which aggregate between the terminals 12 and 22 coagulate, thereby forming the solder portion 33. Thus, the terminals 12 and 22 are electrically connected by the solder portion 33, while the wiring board 10 is bonded to the electronic component 20 by the bonding sheet X. A cured resin portion 34 derived from the matrix resin 31 is formed around the solder portion 33. The cured resin portion 34 contains a thermosetting resin in which the curing progresses at least partially and a solidified thermoplastic resin, and preferably contains a thermosetting resin in a fully cured state and a solidified thermoplastic resin.

As described above, it is possible to mount the electronic component 20 on the wiring board 10 by the solder bonding using the bonding sheet X.

In the bonding sheet X, as described above, the particle size D₅₀ of the contained solder particles which are solder portion forming materials is 12 μm or less, the particle size D₅₀ of the contained flux particles for developing the oxide film removal function with respect to the solder particles is 30 μm or less, and the ratio of the particle size D₉₀ of both particles with respect to the sheet thickness T is 0.95 or less. Such a configuration is suitable for thinly fabricating the bonding sheet X with its surface unevenness suppressed, even when the sheet thickness T is, for example, 50 μm or less.

Then, the above-described configuration in which the particle size D₅₀ of the solder particles is 12 μm or less in the bonding sheet X suitable for being thinly fabricated is suitable for forming the minute solder portion 33 corresponding to its thinness from the solder particles 32 (the plurality of solder particles 32 present in a predetermined subregion), for example, between the wiring board 10 and the electronic component 20 as described above using the bonding sheet X. Being suitable for forming the minute solder portion 33 is preferable for forming the plurality of solder portions 33 at a fine pitch.

Further, the above-described configuration in which the particle size D₅₀ of the contained flux particles of the bonding sheet X is 30 μm or less is suitable for realizing the uniform dispersion state of the flux particles with respect to the solder particles 32 having the particle size D₅₀ of 12 μm or less in the matrix resin 31, and therefore, is suitable for developing the excellent oxide film removal function with respect to the solder particles 32 in the flux particles during the solder bonding process. By developing the oxide film removal function of the flux particles with respect to the solder particles 32 during heating for the solder bonding, the solder particles 32 are appropriately melted and aggregated.

According to the bonding sheet X in which each provided configuration can cooperate as described above, for example, when the electronic component in which narrow terminals are disposed on the surface at a fine pitch is used for the solder bonding for being mounted on the wiring board (solder bonding between a plurality of electronic component terminals and a plurality of substrate terminals facing thereto), a plurality of solder portions are easily formed at a fine pitch using a self-aggregating effect (self-alignment effect) of the melted solder particles for each facing terminal. That is, the bonding sheet X is suitable for forming the plurality of solder portions bonding the objects to be bonded at a fine pitch. Since the bonding sheet X is suitable for forming a small solder portion, it is suitable for shortening the time required for the self-alignment of the melted solder for forming the small solder portion, and therefore, is suitable for the solder bonding by the short-time heating.

### EXAMPLES

### Example 1

As a thermosetting resin, 70 parts by mass of an epoxy resin (trade name “jER828”, bisphenol A epoxy resin, epoxy equivalent of 184 to 194 g/eq, liquid at normal temperature, manufactured by Mitsubishi Chemical Corporation); as a thermoplastic resin, 30 parts by mass of an acrylic resin (trade name “ARUFON UH-2170”, hydroxyl group-containing styrene acrylic polymer, solid at normal temperature, manufactured by TOAGOSEI CO., LTD.); 150 parts by mass of first solder particles (42% by mass of Sn-58% by mass of Bi alloy, melting point of 139° C., spherical shape, particle size D₅₀ of 3 μm, particle size D₉₀ of 6 μm); and as the flux particles, 50 parts by mass of a first malic acid (particle size D₅₀ of 4.4 μm, particle size D₉₀ of 12 μm) were added to methyl ethyl ketone (MEK) to be mixed, thereby preparing a composition having the solid content concentration of 75% by mass. Next, the composition was coated onto a separator to form a coating film, and then, the coating film was dried (drying process). A drying temperature was 80° C., and the drying time was 3 minutes. As described above, a bonding sheet having a thickness of 20 μm was fabricated on the separator. The composition of the bonding sheet of Example 1 is listed in Table 1 (in Tables 1 to 3, the unit of each numerical value representing the composition is relative “parts by mass”).

### Examples 2 and 3

Each bonding sheet of Examples 2 and 3 was fabricated in the same manner as in the bonding sheet of Example 1, except that in the preparation of the composition, as a thermosetting catalyst, 3 parts by mass (Example 2) or 5 parts by mass (Example 3) of 1-benzyl-2-phenylimidazole was further blended.

### Examples 4 to 6

A bonding sheet of Example 4 was fabricated in the same manner as in the bonding sheet of Example 1, a bonding sheet of Example 5 was fabricated in the same manner as in the bonding sheet of Example 2, and a bonding sheet of Example 6 was fabricated in the same manner as in the bonding sheet of Example 3, except that in the preparation of the composition, 150 parts by mass of second solder particles (25% by mass of Sn-55% by mass of Bi-20% by mass of In alloy, melting point of 80° C., spherical shape, particle size D₅₀ of 3 μm, particle size D₉₀ of 6 μm) were blended instead of 150 parts by mass of the first solder particles, and as the flux particles, 50 parts by mass of a first adipic acid (particle size D₅₀ of 4.5 μm, particle size D₉₀ of 15 μm) was blended instead of 50 parts by mass of the above-described first malic acid.

### Example 7

A bonding sheet of Example 7 was fabricated in the same manner as in the bonding sheet of Example 1, except that in the preparation of the composition, 150 parts by mass of second solder particles (25% by mass of Sn-55% by mass of Bi-20% by mass of In alloy, melting point of 80° C., spherical shape, particle size D₅₀ of 3 μm, particle size D₉₀ of 6 μm) were blended instead of 150 parts by mass of the first solder particles; as the flux particles, 50 parts by mass of a second adipic acid (particle size D₅₀ of 21 μm, particle size D₉₀ of 47 μm) was blended instead of 50 parts by mass of the above-described first malic acid; and in the sheet molding, the sheet thickness was changed to 50 μm instead of 20 μm.

### Example 8

A bonding sheet of Example 8 was fabricated in the same manner as in the bonding sheet of Example 1, except that in the sheet molding, the sheet thickness was changed to 15 μm instead of 20 μm.

### Example 9

A bonding sheet of Example 9 was fabricated in the same manner as in the bonding sheet of Example 1, except that in the preparation of the composition, the mixing amount of the first malic acid was changed to 25 parts by mass instead of 50 parts by mass, and in the sheet molding, the sheet thickness was changed to 50 μm instead of 20 μm.

### Examples 10 to 12

A bonding sheet of Example 10 was fabricated in the same manner as in the bonding sheet of Example 1, a boding sheet of Example 11 was fabricated in the same manner as in the bonding sheet of Example 2, and a bonding sheet of Example 12 was fabricated in the same manner in as the bonding sheet of Example 3, except that in the preparation of the composition, as the flux particles, 50 parts by mass of a second malic acid (particle size D₅₀ of 8.3 μm, particle size D₉₀ of 24 μm) was blended instead of 50 parts by mass of the above-described first malic acid, and in the sheet molding, the sheet thickness was changed to 30 μm instead of 20 μm.

### Examples 13 to 15

A bonding sheet of Example 13 was fabricated in the same manner as in the bonding sheet of Example 1, a boding sheet of Example 14 was fabricated in the same manner as in the bonding sheet of Example 2, and a bonding sheet of Example 15 was fabricated in the same manner as in the bonding sheet of Example 3, except that in the preparation of the composition, 150 parts by mass of second solder particles (25% by mass of Sn-55% by mass of Bi-20% by mass of In alloy, melting point of 80° C., spherical shape, particle size D₅₀ of 3 μm, particle size D₉₀ of 6 μm) were blended instead of 150 parts by mass of the first solder particles; as the flux particles, 50 parts by mass of a third adipic acid (particle size D₅₀ of 8.2 μm, particle size D₉₀ of 25 μm) was blended instead of 50 parts by mass of the above-described first malic acid, and in the sheet molding, the sheet thickness was changed to 30 μm instead of 20 μm.

### Example 16

A bonding sheet of Example 16 was fabricated in the same manner as in the bonding sheet of Example 1, except that in the preparation of the composition, the mixing amount of the first malic acid was changed to 25 parts by mass instead of 50 parts by mass.

### Example 17

A bonding sheet of Example 17 was fabricated in the same manner as in the bonding sheet of Example 1, except that in the preparation of the composition, 1 part by mass of a first colorant (trade name “BLACK 305”, manufactured by Fukui Yamada Chemical Co., Ltd.) was further blended.

### Example 18

A bonding sheet of Example 17 was fabricated in the same manner as in the bonding sheet of Example 1, except that in the preparation of the composition, 3 parts by mass of a second colorant (trade name “OIL BLACK 860”, manufactured by ORIENT CHEMICAL INDUSTRIES CO., LTD.) was further blended.

### Example 19

A bonding sheet of Example 19 was fabricated in the same manner as in the bonding sheet of Example 1, except that in the preparation of the composition, 3 parts by mass of a third colorant (trade name “9154 BLACK”, manufactured by TOKUSHIKI CO., LTD.) was further blended.

### Example 20

A bonding sheet of Example 20 was fabricated in the same manner as in the bonding sheet of Example 4, except that in the preparation of the composition, 3 parts by mass of a second colorant (trade name “OIL BLACK 860”, manufactured by ORIENT CHEMICAL INDUSTRIES CO., LTD.) was further blended.

### Comparative Example 1

A bonding sheet of Comparative Example 1 was fabricated in the same manner as in the bonding sheet of Example 1, except that in the preparation of the composition, as the flux particles, 50 parts by mass of a fourth adipic acid (particle size D₅₀ of 92 μm, particle size D₉₀ of 170 μm) was blended instead of 50 parts by mass of the above-described first malic acid, and in the sheet molding, the sheet thickness was changed to 200 μm instead of 20 μm.

### Comparative Example 2

A fabrication operation of a bonding sheet was advanced in the same manner as in Example 1, except that in the preparation of the composition, the mixing amount of the epoxy resin (trade name “jER828”, manufactured by Mitsubishi Chemical Corporation) was changed to 100 parts by mass instead of 70 parts by mass, the acrylic resin (trade name “ARUFON UH-2170”, manufactured by TOAGOSEI CO., LTD.) was not blended, and as the flux particles, 50 parts by mass of the above-described first adipic acid was blended instead of 50 parts by mass of the above-described first malic acid. However, a coating film formed by coating of the composition onto the separator could not retain the sheet shape after drying process (i.e., it was not solid enough to maintain the sheet shape), and it was not possible to fabricate a bonding sheet.

### Comparative Example 3

A fabrication operation of a bonding sheet was advanced in the same manner as in Example 1, except that in the preparation of the composition, the mixing amount of the first solder particles was changed to 50 parts by mass instead of 150 parts by mass, and as the flux particles, 50 parts by mass of a glutaric acid (particle size D₅₀ of 4.3 μm, particle size D₉₀ of 13 μm) was blended instead of 50 parts by mass of the above-described first malic acid. However, in the drying process after the coating of the composition onto the separator, the glutaric acid (flux particles) in the composition was liquefied, so that repellence occurred on the coating film and it was not possible to fabricate a bonding sheet. It is considered that the glutaric acid used as the flux particles in a form of fine particles can be melted at a temperature lower than the melting point of 95° C., which is shown in a bulk state.

<Measurement of Tensile Elastic Modulus>

A tensile elastic modulus of each of the bonding sheets of Examples 1 to 20 and Comparative Example 1 was examined as follows. First, the bonding sheet and a support tape (thickness T′ of 50 μm, tensile elastic modulus E′ of 0.03 MPa) were attached, thereby obtaining a laminate, and a test piece (width of 10 mmx length of 15 mm) was cut out from the laminate to be prepared. Then, a tensile test was carried out for the test piece using a tensile testing machine (trade name “AGS-50NX”, manufactured by Shimadzu Corporation), and the tensile elastic modulus was measured. In the present tensile test, an initial distance between chucks was 10 mm, a measurement temperature was 25° C., and a tensile rate was 50 mm/min A tensile elastic modulus E₀ of the test piece was derived from a slope of initial straight portion of a stress-strain curve obtained by the tensile test (rising portion of the stress-strain curve in an initial stage of the measurement), and a tensile elastic modulus E of the bonding sheet was derived by the following formula (1) (derivation of the first tensile elastic modulus). The values are listed in Tables 1 to 3 as a first tensile elastic modulus E₁ (MPa). In the following formula (1), E₀ is the tensile elastic modulus of the test piece, T₀ is the thickness of the test piece, E is the tensile elastic modulus of the bonding sheet, T is the thickness of the bonding sheet, E′ is the tensile elastic modulus of the support tape, and T′ is the thickness of the support tape.

E=(E₀×T₀−E′×T′)/T (1)

Further, the tensile elastic modulus after the heat treatment at 160° C. for 20 seconds was examined for each of the bonding sheets of Examples 1 to 20 and Comparative Example 1. Specifically, the tensile elastic modulus of the bonding sheet was derived in the same manner as in the derivation of the first tensile elastic modulus, except that the prepared test piece was subjected to the heat treatment at 160° C. for 20 seconds before the tensile test. The values are listed in Tables 1 to 3 as a second tensile elastic modulus E₂ (MPa). Further, a ratio (E₂/E₁) of the second tensile elastic modulus E₂ to the first tensile elastic modulus E₁ is also listed in Tables 1 to 3.

<Shear Pressure-Sensitive Adhesive Force>

A shear pressure-sensitive adhesive force was measured by a shear test for each of the bonding sheets of Examples 1 to 20 and Comparative Example 1. In the fabrication of a sample for the shear test, first, a sheet piece (10 mm×10 mm) was cut out from the bonding sheet. Next, one surface of the sheet piece was attached to a polyimide plate (10 mm×50 mm) by a crimping operation for reciprocating a 2-kg roller, and the other surface of the sheet piece was attached to another polyimide plate (10 mm×50 mm) by a crimping operation for reciprocating a 2-kg roller. Then, the prepared measurement sample was left to stand under the environment of 25° C. for 30 minutes, and then, under the environment of 25° C., the two polyimide plates which were bonded to each other via the sheet piece in the measurement sample were pulled in an opposite direction at a tensile rate of 5 mm/min, while the tensile force was measured (measurement of a first shear pressure-sensitive adhesive force). The maximum value measured at that time is listed in Tables 1 to 3 as a first shear pressure-sensitive adhesive force F₁ (MPa).

Also, a shear pressure-sensitive adhesive force after the heat treatment at 160° C. for 20 seconds was examined for each of the bonding sheets of Examples 1 to 20 and Comparative Example 1. Specifically, the shear pressure-sensitive adhesive force of the bonding sheet was measured in the same manner as in the measurement of the first shear pressure-sensitive adhesive force, except that the prepared measurement sample was subjected to the heat treatment at 160° C. for 20 seconds before the shear test. The maximum value measured at that time is listed in Tables 1 to 3 as a second shear pressure-sensitive adhesive force F₂ (MPa). A ratio (F₂/F₁) of the second shear pressure-sensitive adhesive force F₂ to the first shear pressure-sensitive adhesive force F₁ is also listed in Tables 1 to 3.

<Continuity Test>

A continuity test was carried out for each of the bonding sheets of Examples 1 to 20 and Comparative Example 1 as follows. First, two wiring boards were attached to each other via a bonding sheet, thereby preparing a sample for solder bonding. Each of the wiring boards had a transparent glass substrate, and a plurality of linear wirings (width of 30 μm) formed thereon. The plurality of linear wirings are disposed in parallel on one surface of the glass substrate (space between adjacent wirings of 30 μm). In the sample for solder bonding, the two wiring boards were bonded to each other via the bonding sheet in a form in which a wiring of one wiring board faced a wiring of the other wiring board. Next, the sample was subjected to the heat treatment at 160° C. for 20 seconds. Next, after lowering the temperature of the sample, a resistance value between the facing one pair of wirings via the bonding sheet through the heat treatment was measured. A digital multimeter PC-500a (manufactured by Sanwa Electric Instrument Co., Ltd.) was used to measure the resistance value. Then, conductivity of the bonding sheet after the heat treatment was evaluated based on the following criteria: in the present continuity test, a case where the resistance value could be measured (i.e., when the facing wirings were electrically conducted) was evaluated as “Excellent”, and a case where the resistance value could not be measured (i.e., when the facing wirings were not electrically conducted) was evaluated as “Bad”. The results are listed in Tables 1 to 3.

(Cohesiveness)

Cohesiveness of the solder particles by heating was examined for each of the bonding sheets of Examples 1 to 20 and Comparative Example 1. First, the same measurement sample as the one used for the above-described continuity test was prepared. Next, the sample was subjected to the heat treatment at 160° C. for 60 seconds. During the heat treatment, by using a digital microscope (trade name “VHX-7000”, manufactured by KEYENCE CORPORATION), the bonding sheet between the wiring boards in the sample was observed at an enlargement magnification of 200 times, and the time required for all the solder particles in the observation field to melt and aggregate between the facing wirings (aggregation completion time) was measured. Then, the cohesiveness of the bonding sheet by heating was evaluated based on the following criteria: a case where the aggregation completion time was 30 seconds or less was evaluated as “Excellent”, and a case where the aggregation completion time was above 30 seconds was evaluated as “Bad”. The results are listed in Tables 1 to 3.

(Uniformity of Aggregation)

Uniformity of aggregation of the solder particles during the heating was examined for each of the bonding sheets of Examples 1 to 20 and Comparative Example 1 as follows. First, the bonding sheet was attached to the same wiring board (width of each linear wiring disposed in parallel of 30 μm, space between the wirings of 30 μm) as the one used for the above-described continuity test, thereby preparing a measurement sample. The bonding sheet in the sample included a plurality of partial regions (region on the wiring) which were located on the wiring (i.e., faced the wiring) of the wiring board, and a plurality of partial regions (region on the space) which were located on the space between the wirings (i.e., faced the space between the wirings) of the wiring board. Next, the sample was subjected to the heat treatment at 160° C. for 60 seconds. During the heat treatment, by using the above-described digital microscope (trade name “VHX-7000”), the bonding sheet on the wiring board was observed from the opposite side to the wiring board at an enlargement magnification of 200 times, and the time required for the solder particles to melt and start to move toward the region on the wiring (time from the start of heating at 160° C.) was measured in each of the 10 selected regions (regions arbitrarily selected within a range of 1000 μm×1000 μm of the bonding sheet). Then, the uniformity of the aggregation of the solder particles during the heating was evaluated for the bonding sheet based on the following criteria: a case where the time required for the phenomenon that the solder particles in the selected region melted and started to move toward the region on the wiring occurred at 7 locations or more of the above-described 10 selected regions was 5 seconds or less was evaluated as “Excellent”, a case where the time was above 5 seconds and 7 seconds or less was evaluated as “Good”, and a case where the time was above 7 seconds was evaluated as “Bad”. The results are listed in Tables 1 to 3.

<Total Light Transmittance>

A total light transmittance after heating was examined for each of the bonding sheets of Examples 1, 4, and 17 to 20 as follows.

First, a measurement sample was fabricated. More specifically, first, an exposed surface-side of the bonding sheet with a separator was attached to a first glass substrate (non-alkali glass, thickness of 1 mm, manufactured by Matsunami Glass Ind., Ltd.). Next, the separator was peeled from the bonding sheet on the first glass substrate. Next, a solution containing an appropriate amount of spacer particles (silica particles, average particle size of 10 μm) was coated around the bonding sheet on the first glass substrate. Then, the second glass substrate (non-alkali glass, thickness of 1 mm, manufactured by Matsunami Glass Ind., Ltd.) was bonded to the first glass substrate via the bonding sheet (temporary bonding). The laminate thus obtained was then subjected to the heat treatment at 160° C. for 20 seconds. Thus, in the bonding sheet between the first and second glass substrates, the solder particles were aggregated, and the thermosetting resin was cured. As described above, the measurement sample was fabricated. In the measurement sample, the spacer particles were interposed between the first glass substrate and the second glass substrate. The presence of the spacer particles between the first glass substrate and the second glass substrate resulted in the same separation distance between the first glass substrate and the second glass substrate between the samples.

Next, a total light transmittance (JIS K7361) of the measurement sample was measured using a total light transmittance measurement device. The results are shown in Table 3. Bonding sheets 10 of Examples 17 to 20 had a significantly lower total light transmittance as compared with the bonding sheets of Examples 1 and 4.

TABLE 1

| | | Ex. 1 | Ex. 2 | Ex. 3 | Ex. 4 | Ex. 5 | Ex. 6 | Ex. 7 | Ex. 8 | Ex. 9 |
|---|---|---|---|---|---|---|---|---|---|---|
| Epoxy Resin | | 70 | 70 | 70 | 70 | 70 | 70 | 70 | 70 | 70 |
| (Liquid at Normal Temperature) | | | | | | | | | | |
| Acrylic Resin | | 30 | 30 | 30 | 30 | 30 | 30 | 30 | 30 | 30 |
| (Solid at Normal Temperature) | | | | | | | | | | |
| First Solder Particle | | 150 | 150 | 150 | — | — | — | — | 150 | 150 |
| (Sn—Bi, D₅₀ 3 μm D₉₀ 6 μm) | | | | | | | | | | |
| Second Solder Particle | | — | — | — | 150 | 150 | 150 | 150 | — | — |
| (Sn—Bi—In, D₅₀ 3 μm D₉₀ 6 μm) | | | | | | | | | | |
| Flux | First Malic Acid | 50 | 50 | 50 | — | — | — | — | 50 | 25 |
| Particle | (D₅₀ 4.4 μm D₉₀ 12 μm) | | | | | | | | | |
| | Second Malic Acid | — | — | — | — | — | — | — | — | — |
| | (D₅₀ 8.3 μm D₉₀ 24 μm) | | | | | | | | | |
| | First Adipic Acid | — | — | — | 50 | 50 | 50 | — | — | — |
| | (D₅₀ 4.5 μm D₉₀ 15 μm) | | | | | | | | | |
| | Second Adipic Acid | — | — | — | — | — | — | 50 | — | — |
| | (D₅₀ 21 μm D₉₀ 47 μm) | | | | | | | | | |
| | Third Adipic Acid | — | — | — | — | — | — | — | — | — |
| | (D₅₀ 8.2 μm D₉₀ 25 μm) | | | | | | | | | |
| | Fourth Adipic Acid | — | — | — | — | — | — | — | — | — |
| | (D₅₀ 92 μm D₉₀ 170 μm) | | | | | | | | | |
| | Glutaric Acid | — | — | — | — | — | — | — | — | — |
| | (D₅₀ 4.3 μm D₉₀ 13 μm) | | | | | | | | | |

| | | | | | | | | | |
|---|---|---|---|---|---|---|---|---|---|
| Thermosetting Catalyst (1-benzyl-2-phenyl | — | 3 | 5 | — | 3 | 5 | — | — | — |
| Imidazole, Liquid at Normal Temperature) | | | | | | | | | |
| Sheet Thickness T (μm) | 20 | 20 | 20 | 20 | 20 | 20 | 50 | 15 | 15 |
| D₉₀/T of Solder Particle | 0.30 | 0.30 | 0.30 | 0.30 | 0.30 | 0.30 | 0.12 | 0.40 | 0.40 |
| D₉₀/T of Flux Particle | 0.60 | 0.60 | 0.60 | 0.75 | 0.75 | 0.75 | 0.94 | 0.80 | 0.80 |
| D₅₀ of Flux Particle/D₅₀ of Solder Particle | 1.47 | 1.47 | 1.47 | 1.50 | 1.50 | 1.50 | 7.0 | 1.47 | 1.47 |
| First Tensile Elastic Modulus E₁ (MPa) | 2.5 | 2.7 | 10 | 2.1 | 2.1 | 3.2 | 2.2 | 2.5 | 2.3 |
| Second Tensile Elastic Modulus E₂ (MPa) | 68 | 64 | 150 | 20 | 23 | 29 | 21 | 69 | 38 |
| E₂/E₁ | 27 | 24 | 15 | 10 | 11 | 9 | 10 | 27.6 | 16.5 |
| First Shear Pressure-Sensitive Adhesive | 0.27 | 0.34 | 0.39 | 0.25 | 0.37 | 0.38 | 0.23 | 0.29 | 0.27 |
| Force F₁ (MPa) | | | | | | | | | |
| Second Shear Pressure-Sensitive Adhesive | 0.81 | 0.96 | 1.00 | 0.83 | 0.71 | 0.99 | 0.73 | 0.84 | 0.70 |
| Force F₂ (MPa) | | | | | | | | | |
| F₂/F₁ | 3.0 | 2.8 | 2.6 | 3.3 | 1.9 | 2.6 | 3.2 | 2.9 | 2.59 |
| Evaluation of Continuity Test | Excellent | Excellent | Excellent | Excellent | Excellent | Excellent | Excellent | Excellent | Excellent |
| Evaluation of Cohesiveness | Excellent | Excellent | Excellent | Excellent | Excellent | Excellent | Excellent | Excellent | Excellent |
| Evaluation of Uniformity of Aggregation | Excellent | Excellent | Excellent | Excellent | Excellent | Excellent | Good | Excellent | Excellent |

TABLE 2

| | | | | | | | | | Compar- | Compar- | Compar- |
|---|---|---|---|---|---|---|---|---|---|---|---|
| | | | | | | | | | ative | ative | ative |
| | | Ex. 10 | Ex. 11 | Ex. 12 | Ex. 13 | Ex. 14 | Ex. 15 | Ex. 16 | Ex. 1 | Ex. 2 | Ex. 3 |
| Epoxy Resin | | 70 | 70 | 70 | 70 | 70 | 70 | 70 | 70 | 100 | 70 |
| (Liquid at Normal Temperature) | | | | | | | | | | | |
| Acrylic Resin | | 30 | 30 | 30 | 30 | 30 | 30 | 30 | 30 | — | 30 |
| (Solid at Normal Temperature) | | | | | | | | | | | |
| First Solder Particle | | 150 | 150 | 150 | — | — | — | 150 | 150 | 150 | 50 |
| (Sn—Bi, D₅₀ 3 μm D₉₀ 6 μm) | | | | | | | | | | | |
| Second Solder Particle | | — | — | — | 150 | 150 | 150 | — | — | — | — |
| (Sn—Bi—In, D₅₀ 3 μm D₉₀ 6 μm) | | | | | | | | | | | |
| Flux | First Malic Acid | — | — | — | — | — | — | 25 | — | — | — |
| Particle | (D₅₀ 4.4 μm D₉₀ 12 μm) | | | | | | | | | | |
| | Second Malic Acid | 50 | 50 | 50 | — | — | — | — | — | — | |
| | (D₅₀ 8.3 μm D₉₀ 24 μm) | | | | | | | | | | |
| | First Adipic Acid | — | — | — | — | — | — | — | — | 50 | — |
| | (D₅₀ 4.5 μm D₉₀ 15 μm) | | | | | | | | | | |
| | Second Adipic Acid | — | — | — | — | — | — | — | — | — | — |
| | (D₅₀ 21 μm D₉₀ 47 μm) | | | | | | | | | | |
| | Third Adipic Acid | — | — | — | 50 | 50 | 50 | — | — | — | — |
| | (D₅₀ 8.2 μm D₉₀ 25 μm) | | | | | | | | | | |
| | Fourth Adipic Acid | — | — | — | — | — | — | — | 50 | — | — |
| | (D₅₀ 92 μm D₉₀ 170 μm) | | | | | | | | | | |
| | Glutaric Acid | — | — | — | — | — | — | — | — | — | 50 |
| | (D₅₀ 4.3 μm D₉₀ 13 μm) | | | | | | | | | | |

| | | | | | | | | | | |
|---|---|---|---|---|---|---|---|---|---|---|
| Thermosetting Catalyst (1-benzyl-2-phenyl | — | 3 | 5 | — | 3 | 5 | — | — | — | — |
| Imidazole, Liquid at Normal Temperahire) | | | | | | | | | | |
| Sheet Thickness T (μm) | 30 | 30 | 30 | 30 | 30 | 30 | 20 | 200 | | |
| D₉₀/T of Solder Particle | 0.20 | 0.20 | 0.20 | 0.20 | 0.20 | 0.20 | 0.3 | 0.03 | | |
| D₉₀/T of Flux Particle | 0.80 | 0.80 | 0.80 | 0.83 | 0.83 | 0.83 | 0.6 | 0.S5 | | |
| D₅₀ of Flux Particle/D₅₀ of Solder Particle | 2.8 | 2.8 | 2.8 | 2.7 | 2.7 | 2.7 | 1.47 | 31 | | |
| First Tensile Elastic Modulus E₁ (MPa) | 2.3 | 2.9 | 9.0 | 2.3 | 1.9 | 2.9 | 2.3 | Unmea- | | |
| | | | | | | | | sured | | |
| Second Tensile Elastic Modulus E₂ (MPa) | 73 | 69 | 120 | 22 | 25 | 30 | 37 | Unmea- | | |
| | | | | | | | | sured | | |
| E₂/E₁ | 32 | 24 | 13 | 10 | 13 | 10 | 16.1 | Unmea- | | |
| | | | | | | | | sured | | |
| First Shear Pressure-Sensitive Adhesive | 0.29 | 0.31 | 0.37 | 0.27 | 0.32 | 0.39 | 0.26 | Unmea- | | |
| Force F₁ (MPa) | | | | | | | | sured | | |
| Second Shear Pressure-Sensitive Adhesive | 0.83 | 0.94 | 0.98 | 0.70 | 0.69 | 1.01 | 0.68 | Unmea- | | |
| Force F₂ (MPa) | | | | | | | | sured | | |
| F₂/F₁ | 2.9 | 3.0 | 2.6 | 2.6 | 2.2 | 2.6 | 2.62 | Unmea- | | |
| | | | | | | | | sured | | |
| Evaluation of Continuity Test | Excel- | Excel- | Excel- | Excel- | Excel- | Excel- | Excel- | Uneval- | | |
| | lent | lent | lent | lent | lent | lent | lent | uated | | |
| Evaluation of Cohesiveness | Excel- | Excel- | Excel- | Excel- | Excel- | Excel- | Excel- | Uneval- | | |
| | lent | lent | lent | lent | lent | lent | lent | uated | | |
| Evaluation of Uniformity of Aggregation | Excel- | Excel | Excel- | Excel- | Excel- | Excel- | Excel- | Uneval- | | |
| | lent | lent | lent | lent | lent | lent | lent | uated | | |

TABLE 3

| | | Ex. 1 | Ex. 4 | Ex. 17 | Ex. 18 | Ex. 19 | Ex. 20 |
|---|---|---|---|---|---|---|---|
| Epoxy Resin | | 70 | 70 | 70 | 70 | 70 | 70 |
| (Liquid at Normal Temperature) | | | | | | | |
| Acrylic Resin | | 30 | 30 | 30 | 30 | 30 | 30 |
| (Solid at Normal Temperature) | | | | | | | |
| First Solder Particle | | 150 | — | 150 | 150 | 150 | — |
| (Sn—Bi, D₅₀ 3 μm D₉₀ 6 μm) | | | | | | | |
| Second Solder Particle | | — | 150 | — | — | — | 150 |
| (Sn—Bi—In, D₅₀ 3 μm D₉₀ 6 μm) | | | | | | | |
| Flux | First Malic Acid | 50 | — | 50 | 50 | 50 | — |
| Particle | (D₅₀ 4.4 μm D₉₀ 12 μm) | | | | | | |
| | First Adipic Acid | — | 50 | — | — | — | 50 |
| | (D₅₀ 4.5 μm D₉₀ 15 μm) | | | | | | |

| | | | | | | |
|---|---|---|---|---|---|---|
| First Colorant (Black 305) | — | — | 1 | — | — | — |
| Second Colorant (OIL BLACK 860) | — | — | — | 3 | — | 3 |
| Third Colorant (9154 BLACK) | — | — | — | — | 3 | — |
| Sheet Thickness T (μm) | 20 | 20 | 20 | 20 | 20 | 20 |
| D₉₀/T of Solder Particle | 0.30 | 0.30 | 0.30 | 0.30 | 0.30 | 0.30 |
| D₉₀/T of Flux Particle | 0.60 | 0.75 | 0.60 | 0.60 | 0.60 | 0.75 |
| D₅₀ of Flux Particle/D₅₀ of Solder Particle | 1.47 | 1.57 | 1.47 | 1.47 | 1.47 | 1.50 |
| First Tensile Elastic Modulus E₁ (MPa) | 2.5 | 2.1 | 2.5 | 2.4 | 2.0 | 2.6 |
| Second Tensile Elastic Modulus E₂ (MPa) | 68 | 20 | 67 | 65 | 18 | 69 |
| E₂/E₁ | 27 | 10 | 27 | 27 | 9.0 | 27 |
| First Shear Pressure-Sensitive Adhesive | 0.27 | 0.25 | 0.26 | 0.26 | 0.24 | 0.27 |
| Force F₁ (MPa) | | | | | | |
| Second Shear Pressure-Sensitive Adhesive | 0.81 | 0.83 | 0.83 | 0.82 | 0.80 | 0.82 |
| Force F₂ (MPa) | | | | | | |
| F₂/F₁ | 3.0 | 3.3 | 3.2 | 3.2 | 3.3 | 3.0 |
| Total Light Transmittance (%) after | 84.4 | 83.2 | 39.9 | 69.7 | 69.8 | 40.7 |
| Heating | | | | | | |
| Evaluation of Continuity Test | Excellent | Excellent | Excellent | Excellent | Excellent | Excellent |
| Evaluation of Cohesiveness | Excellent | Excellent | Excellent | Excellent | Excellent | Excellent |
| Evaluation of Uniformity of Aggregation | Excellent | Excellent | Excellent | Excellent | Excellent | Excellent |

### INDUSTRIAL APPLICATION

The bonding sheet of the present invention can be, for example, used as a solder material supply material for solder bonding of an electronic component with respect to a wiring board.

### DESCRIPTION OF REFERENCE NUMERALS

X Bonding sheet
S Separator
10 Wiring board
12 Terminal
20 Electronic component
22 Terminal
31 Matrix resin
32 Solder particle
33 Solder portion
34 Cured resin portion

1. A bonding sheet comprising:
a matrix resin, a plurality of solder particles, and a plurality of flux particles, and having a sheet thickness T, wherein
a particle size D₅₀ of the solder particles is 12 μm or less,
a particle size D₅₀ of the flux particles is 30 μm or less, and
a ratio of a particle size D₉₀ of the solder particles and a particle size D₉₀ of the flux particles to the sheet thickness T is 0.95 or less.

2. The bonding sheet according to claim 1, wherein
a ratio of the particle size D₅₀ of the flux particles to the particle size D₅₀ of the solder particles is 8 or less.

3. The bonding sheet according to claim 1, wherein
the sheet thickness T is 50 μm or less.

4. The bonding sheet according to claim 1, wherein
a ratio of a second tensile elastic modulus at 25° C. of the bonding sheet after heat treatment at 160° C. for 20 seconds to a first tensile elastic modulus at 25° C. is 5 or more.

5. The bonding sheet according to claim 1, wherein
the first tensile elastic modulus at 25° C. of the bonding sheet is 10 MPa or less.

6. The bonding sheet according to claim 1, wherein
the second tensile elastic modulus at 25° C. of the bonding sheet after heat treatment at 160° C. for 20 seconds is above 10 MPa.

7. The bonding sheet according to claim 1, wherein
a ratio of a second shear pressure-sensitive adhesive force at 25° C. of the bonding sheet showing for a polyimide plane surface after the bonding sheet being bonded to the polyimide plane surface and subsequently, subjected to a heat treatment at 160° C. for 20 seconds to a first shear pressure-sensitive adhesive force at 25° C. of the bonding sheet showing for the polyimide plane surface after the bonding sheet being bonded to the polyimide plane surface is 1.2 or more.

8. The bonding sheet according to claim 1 further comprising a colorant.

9. The bonding sheet according to claim 8, wherein
a total light transmittance at least after heating is 70% or less.
